(19) United States
(12) Patent Application Publication
(10) Pub. No.: US 2014/0183649 A1
(43) Pub. Date: Jul. 3, 2014

(54) SEMICONDUCTOR DEVICE HAVING METAL GATE AND HIGH-K DIELECTRIC LAYER AND METHOD FOR MANUFACTURING THE SAME

(71) Applicant: SK HYNIX INC., Gyeonggi-do (KR)

(72) Inventors: Seung-Mi LEE, Gyeonggi-do (KR); Yun-Hyuck JI, Gyeonggi-do (KR)

(73) Assignee: SK HYNIX INC., Gyeonggi-do (KR)

(21) Appl. No.: 13/844,949

(22) Filed: Mar. 16, 2013

(30) Foreign Application Priority Data
Dec. 28, 2012 (KR) 10-2012-0157283

(51) Int. Cl. H01L 29/51; H01L 27/092

(52) U.S. Cl. CPC H01L 29/518; H01L 27/092
USPC 257/369; 257/410

(57) ABSTRACT

A semiconductor device includes an N-channel transistor configured to have a first gate dielectric layer, a first metal containing gate electrode and a dipole forming layer, wherein the first metal containing gate electrode is formed on the first gate dielectric layer, and the dipole forming layer is formed on an interface of the first gate dielectric layer and the first metal containing gate electrode, and a P-channel transistor configured to have a channel region, a second gate dielectric layer and a second metal containing gate electrode, wherein the channel region has threshold voltage adjusting species, the second gate dielectric layer is formed on the channel region, and the second metal containing gate electrode has effective work function adjusting species of the second gate dielectric layer.

### CROSS-REFERENCE TO RELATED APPLICATIONS

The present application claims priority of Korean Patent Application No. 10-2012-0157283, filed on Dec. 28, 2012, which is incorporated herein by reference in its entirety.

### BACKGROUND

1. Field

Exemplary embodiments of the present invention relate to a semiconductor device, and more particularly, to a semiconductor device having a metal gate and a high-k dielectric layer and a method for manufacturing the same.

2. Description of the Related Art

A complementary metal-oxide semiconductor (CMOS) device may be fabricated to decrease a threshold voltage of an N-channel transistor and a P-channel transistor in order to perform an operation at a high speed operation. An N-type polysilicon may be used as a gate electrode of the N-channel transistor, and a P-type polysilicon may be used as a gate electrode of P-channel transistor.

However, a degradation of a drive current caused by depletion of the polysilicon occurs in the CMOS device according as a transistor may be miniaturized. The depletion of the polysilicon represents that a doping concentration of a dopent may be lowered on an interface of a gate dielectric layer. The dopent doped on the polysilicon may be outwardly spread and the doping concentration may be lowered.

Thus, the N-type polysilicon and the P-type polysilicon have a limitation on optimizing the threshold of each transistor.

Recently, a transistor having a metal gate electrode, in which a metal may be used as a material of a gate electrode, has been developed according to the miniaturization of the transistor. A metal having a low work function is used in the N-channel transistor, and a metal having a high work function is used in the P-channel transistor. Here, the metal having the low work function is a material having a value of the work function of the N-type polysilicon, for example, below 4.1 eV. The metal having the high work function is a metal having a value of the cork function of the P-type polysilicon, for example, above 4.7 eV.

However, a method for adjusting a work function of a metal may have a limitation on minutely adjusting a threshold value of a transistor. Moreover, since a manufacturing process for adjusting the work function suitable for the N-channel transistor and the P-channel transistor is complicated, productivity may be decreased.

### SUMMARY

Various exemplary embodiments of the present invention are directed to a semiconductor device and a method for manufacturing the same for independently optimizing a threshold voltage of an N-channel transistor and a P-channel transistor.

In accordance with an embodiment of the present invention, a semiconductor device includes an N-channel transistor configured to have a first gate dielectric layer, a first metal containing gate electrode and a dipole forming layer, wherein the first metal containing gate electrode is formed on the first gate dielectric layer, and the dipole forming layer is formed on an interface of the first gate dielectric layer and the first metal containing gate electrode, and a P-channel transistor configured to have a channel region, a second gate dielectric layer and a second metal containing gate electrode, wherein the channel region has threshold voltage adjusting species, the second gate dielectric layer is formed on the channel region, and the second metal containing gate electrode has effective work function adjusting species of the second gate dielectric layer.

In accordance with another embodiment of the present invention, a transistor includes a substrate, a gate dielectric layer configured to be formed on the substrate, and a metal nitride configured to have a gate electrode having nitrogen-rich, wherein the gate electrode is formed on the gate dielectric layer, and the metal nitride further includes an element which is implanted to form a dipole on an interface of the gate dielectric layer by being coupled with nitrogen-rich.

In accordance with another embodiment of the present invention, a method for manufacturing a semiconductor device includes forming a threshold voltage adjusting region below a surface of a substrate of a second region, wherein the substrate has a first region and the second region, forming a gate dielectric layer on an entire surface of the substrate, forming a metal containing layer having a first element on the gate dielectric layer, forming a dipole forming layer by implanting a second element on an interface of the gate dielectric layer and the metal containing layer of the first region and forming a gate stack body on the first region and the second region, respectively, by patterning the metal containing layer, the dipole forming layer and the gate dielectric layer.

Each of the first element and the second element may include an element having different electronegativity.

The second element may include arsenic and the first element includes nitrogen.

In the forming of the metal containing layer, the first element includes nitrogen and the metal containing layer may include a metal nitride having nitrogen-rich.

In the forming of the metal containing layer, the metal containing layer includes a titanium nitride having nitrogen-rich as the first element.

The forming of the threshold voltage adjusting region may comprise ion-implanting germanium on a surface of the substrate, forming a sacrificing layer by performing a thermal oxidation on the surface of the substrate, and removing the sacrificing layer.

The implanting of the second element may comprise forming a buffer layer on the metal containing layer, forming a mask pattern for opening the first region on the buffer layer, and ion-implanting arsenic on a lower part of the metal containing layer, which is contacted with the gate dielectric layer, using the mask pattern as an ion implant mask.

The method for manufacturing the semiconductor device may further comprise forming a capping layer on the buffer layer after the ion implanting of the arsenic.

### BRIEF DESCRIPTION OF THE DRAWINGS

FIG. 1 is a diagram illustrating a gate stack body in accordance with an exemplary embodiment of the present invention.

FIGS. 2A to 2J are diagrams illustrating a method for manufacturing a semiconductor device in accordance with an exemplary embodiment of the present invention.

FIG. 3 is a block diagram showing a memory card in accordance with an exemplary embodiment of the present invention.

FIG. 4 is a block diagram showing an electronic system in accordance with an exemplary embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

In the following embodiments, an effective work function is a value acquired from a flat band by a capacitance-voltage (CV) measurement of a gate dielectric layer and a gate electrode, and is influenced on an interface characteristic of a gate electrode and a gate dielectric layer, a material of a gate dielectric layer, and an intrinsic work function of a material used as the gate electrode. The effective work function is different from the intrinsic work function of the material of the gate electrode. The effective work function may be changed by a sort of different element included in the material, a deposition condition and a deposition process of the material used as the gate electrode. The effective work function of the gate stack body may be adjusted by adjusting the effective work function of the gate electrode.

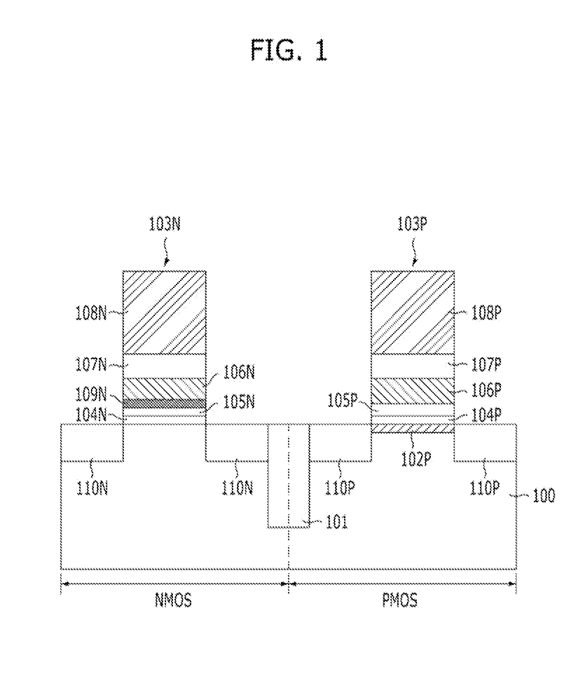

FIG. 1 is a diagram illustrating a gate stack body of a CMOS device in accordance with an exemplary embodiment of the present invention.

Referring to FIG. 1, a substrate 100 includes a first region and a second region. The first region and the second region are separated by an element isolation region 101. The first region and the second region may include a transistor region. For example, a first region is a region where an N-channel region may be formed, NMOS, and a second region is a region where a P-channel region may be formed, PMOS.

A first gate stack body 103N is formed on the substrate 100 of the first region NMOS, and a second gate stack body 103P is formed on the substrate 100 of the second region PMOS. The first gate stack body 103N includes a first gate dielectric layer 105N, a dipole forming layer 109N, a first metal containing gate electrode 106N, a first buffer layer 107N and a first capping layer 108N, which are sequentially stacked. The second gate stack body 103P includes a second gate dielectric layer 105P, a second metal containing gate electrode 106P, a second buffer layer 107P and a second capping layer 108P, which are sequentially stacked.

That is, materials of the first gate stack body 103N on the first region, for example, NMOS are different from materials of the second gate stack body 103P on the second region, for example, PMOS. The first gate stack body 103N and the second gate stack body 103P further includes a first interface layer 104N and a second interface layer 104P formed blow the first gate dielectric layer 105N and the second gate electric 105P, respectively.

A threshold voltage adjusting region 102P is formed on the substrate 100 below the second gate stack body 103P, that is, a channel region. The threshold voltage adjusting region 102P is a crystalline structure, and may have a lot of germanium. The threshold voltage adjusting region 102P may have a silicon germanium structure.

The dipole forming layer 109N included in the first gate stack body 103N is located on an interface layer of the first gate dielectric layer 105N and the first metal containing gate electrode 106N, and forms a dipole. A threshold voltage of the transistor is shifted by forming the dipole. The dipole forming layer 109N may include elements having different electronegativity from each other. For example, the dipole forming layer 109N may include a first element and a second element, and the electronegativity of the first element may be higher or lower than the electronegativity of the second element.

Hereinafter, in exemplary embodiments of the present invention, the first element has higher electronegativity than the second element. The first element may have the nitrogen. Referring to the periodic table of the electronegativity using a falling scale, the nitrogen has electronegativity of, for example, about 3.04. The second element may be selected from elements having smaller electronegativity than the nitrogen, and may include an element on which an ion implantation is performed easily. The second element may include an element which does not degrade the first gate dielectric layer 105N.

Hereinafter, in exemplary embodiments of the present invention, the second element may include arsenic (As). The arsenic (As) may be easily implanted by the ion implantation. The electronegativity of the arsenic (As) is, for example, about 2.18 lower than that of the nitrogen.

As described above, the dipole forming layer 109N includes the first element having a first electronegativity and the second element having a second electronegativity. A value of the first electronegativity may have higher than a value of the second electronegativity. Thus, the dipole is formed. The dipole forming layer 109N may include the arsenic (As) and the nitrogen (N). Since the arsenic (As) and the nitrogen (N) have different electronegativity, the dipole may be formed by the difference of the electronegativity between the arsenic (As) and the nitrogen (N).

The first interface layer 104N and the second interface layer 104P may include a silicon oxide and a silicon oxynitride. For example, the first interface layer 104N and the second interface layer 104P may include SiO₂ and SiON. The first interface layer 104N and the second interface layer 104P improve an electron mobility characteristic by improving an interface characteristic between the first gate dielectric layer 105N and the second dielectric layer 105P.

The first gate dielectric layer 105N and the second dielectric layer 105P include high permittivity (high-k) materials having high-k. The high-k materials have a higher permittivity than permittivity of SiO₂, for example, about 3.0, used in a normal gate dielectric layer. Moreover, the high-k materials are thicker than SiO₂, and have equivalent oxide thickness (EOT) lower than SiO₂. The high-k materials may have higher permittivity than that of the first interface layer 104N and the second interface layer 104P.

The first gate dielectric layer 105N and the second gate dielectric layer 105P include metal oxide, metal silicate, metal silicate nitride, and the like. The metal oxide includes an oxide containing a metal of hafnium (Hf), aluminum (Al), lanthanum (La), zirconium (Zr) and the like. The metal oxide may include hafnium oxide, aluminum oxide, lanthanum oxide, zirconium oxide or combination of these materials. For example, the metal oxide may include HfO₂, Al₂O₃, La₂O₃, ZrO₂ or the combination of these materials. The metal silicate includes silicate containing a metal of hafnium (Hf), zirconium (Zr) and the like. For example, the metal silicate may include hafnium silicate (HfSiO), zirconium silicate (ZrSiO) or the combination of these materials. The metal silicate nitride may include hafnium silicate nitride (HfSiON), zirconium silicate nitride (ZrSiON) or the combination of these materials.

The first metal containing gate electrode 106N and the second metal containing gate electrode 106P include high effective work function materials. The second metal containing gate electrode 106P may include effective work function adjusting species. The second metal containing gate electrode 106P has effective work function appropriate to P-channel transistor by the effective work function adjusting species. Thus, the second metal containing gate electrode 106P may include a P-type effective work function metal containing layer. The P-type effective work function metal containing layer may include a material having an effective work function of 4.7 eV-5.2 eV.

The second metal containing gate electrode 106P may include a first effective work function and may have a second effective work function higher than the first effective work function by an effective work function adjusting species. For example, the first effective work function may include a midgap work function. The second effective work function has a value over than 4.7 eV. Thus, the second metal containing gate electrode 106P includes high effective work function materials. The effective work function adjusting species may include nitrogen (N).

The second metal containing gate electrode 106P has effective work function appropriate to P-channel transistor by the effective work function adjusting species. Thus, the second metal containing gate electrode 106P may include P-type effective work function metal containing layer. The second metal containing gate electrode 106P may include nitrogen-rich metal nitride which is metal nitride having nitrogen (N) much more than stoichiometric composition ratio of titanium and nitrogen. The metal nitride may include titanium nitride. The second metal containing gate electrode 106P may include the titanium nitride having the effective work function increase species. The second metal containing gate electrode 106P may include the nitrogen (N) as the titanium nitride having the effective work function increase species. Thus, the second metal containing gate electrode 106P may include nitrogen-rich titanium nitride (N-rich tiN) which represents titanium nitride having nitrogen (N) much more than stoichiometric composition ratio of the titanium and the nitrogen. The titanium nitride has different work function according to the composition ratio of the titanium and the nitrogen. For example, the nitrogen-rich titanium nitride has a work function suitable for the P-channel transistor. On the contrary, titanium-rich titanium nitride has a work function suitable for an N-channel transistor. Thus, titanium-rich titanium nitride may have a low effective work function. The nitride-rich titanium nitride may be formed by a physical vapor deposition (PVD). Thus, the composition ratio of the titanium and the nitrogen is easily adjusted. Since the second metal containing gate electrode 106P has the high effective work function suitable for the P-channel transistor, the nitrogen-rich titanium nitride is formed as the second metal containing gate electrode 106P. The composition ratio of the titanium and the nitrogen is adjusted by selectively adjusting amount of the nitrogen when the nitrogen-rich titanium nitride is formed. For example, the amount of the nitrogen may be adjusted to have, for example, 20-200 sccm. The nitrogen-rich titanium nitride having the high effective work function of 4.7-5.1 eV may be formed by controlling the amount of the nitrogen. The nitrogen-rich titanium nitride may be formed by an atomic layer deposition (ALD).

The first metal containing gate electrode 106N may include same materials as those of the second metal containing gate electrode 106P. Thus, the first metal containing gate electrode 106N may include nitrogen-rich metal nitride, and include nitrogen-rich titanium nitride (N-rich TiN).

Nitrogen (N) included in the first metal containing gate electrode 106N may perform a function of dipole forming species.

The first buffer layer 107N and the second buffer layer 107P are materials for absorbing an ion impact during an ion implant process. The first buffer layer 107N and the second buffer layer 107P may include silicon containing materials. The first buffer layer 107N and the second buffer layer 107P may include a silicon layer. The silicon layer may include an undoped silicon layer were a dopent is undoped.

The first capping layer 108N and the second capping layer 108P may include silicon containing layer. The first capping layer 108N and the second capping layer 108P may include doped silicon containing layer. For example, the first capping layer 108N and the second capping layer 108P may include an N-type silicon layer or a P-type silicon layer. The first buffer layer 107N, the second buffer layer 107P, the first capping layer 108N and the second capping layer 108P may perform a function of an oxide prevention layer for preventing the first metal containing electrode 106N and the second metal containing electrode 106P from being oxidized. Each of the first capping layer 108N and the second capping layer 108P may include a doped silicon layer. A conductive type of the doped silicon layer may be an N-type or a P-type irrespective of the N-channel transistor and the P-channel transistor. That is, the N-type silicon layer or the P-type silicon layer may be formed on the first region (NMOS) or the second region (PMOS). Moreover, the N-type silicon layer may be formed on all of the first region (NMOS) and the second region (PMOS). That is, the first capping layer 108N and the second capping layer 108P may be formed with similar or the same materials and have similar or the same conductivity on the first region (NMOS) and the second region (PMOS).

A low resistance metal containing layer (not shown) may be further formed on the first capping layer 108N and the second capping layer 108P. The low resistance metal containing layer (not shown) may include tungsten. The low resistance metal containing layer lowers a resistance of the gate stack body.

The first source/drain 110N is formed on the substrate 100 of both sides of the first gate stack body 103N. The second source/drain 110P is formed on the substrate 100 of both sides of the second gate stack body 103P. The first source/drain 103N is an N-type source/drain, and the second source/drain 103P is a P-type source/drain.

The threshold voltage adjusting region 102P is formed on the substrate below the second gate stack body 103P. The threshold voltage adjusting region 102P includes, for example, germanium-rich material. The threshold voltage adjusting region 102P may have germanium-rich silicon germanium structure.

Referring to FIG. 1, the N-channel transistor having the first gate stack body 103N and the P-channel transistor having the second gate stack body 103P are formed on the substrate 100. The threshold voltage adjusting region 102P is formed on a channel region of the P-channel transistor.

As described above, the dipole forming layer 109N of the first gate stack body 103N is formed on an interface layer of the first metal containing gate electrode 106N and the first gate dielectric layer 105N. Thus, the threshold voltage of the N-channel transistor may be shifted. More specifically, the dipole is formed according to the electronegativity difference of elements included in the dipole forming layer 109N which is formed on the interface layer of the first metal containing gate electrode 106N and the first gate dielectric layer 105N. This dipole shifts the threshold voltage of the N-channel transistor.

Since the threshold voltage adjusting region 102P is formed below the second gate stack body 103P, the threshold voltage of the P-channel transistor may be shifted. More specifically, an energy band gap is reduced by forming a germanium-rich region, and thus, the threshold voltage suitable for the P-channel transistor may be adjusted. Moreover, the threshold voltage of the P-channel transistor may be reduced by using effective work function adjusting species-rich materials as the second metal containing gate electrode 106P.

In conclusion, in the embodiment of the present invention, the threshold voltages of the N-channel transistor and the P-channel transistor may be independently adjusted during an integration process of CMOS device.

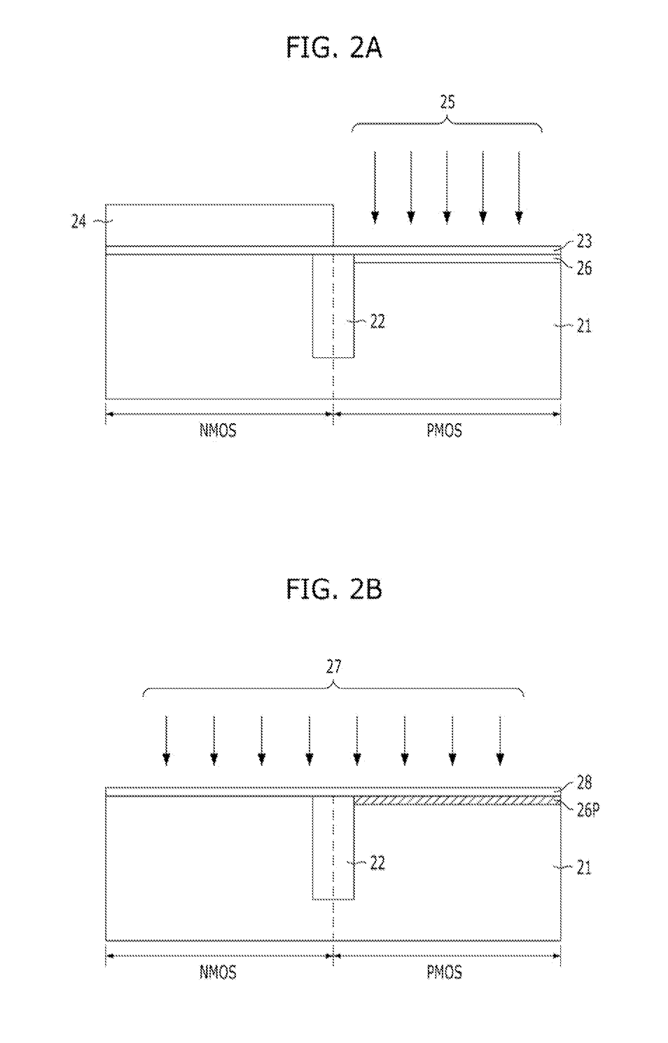

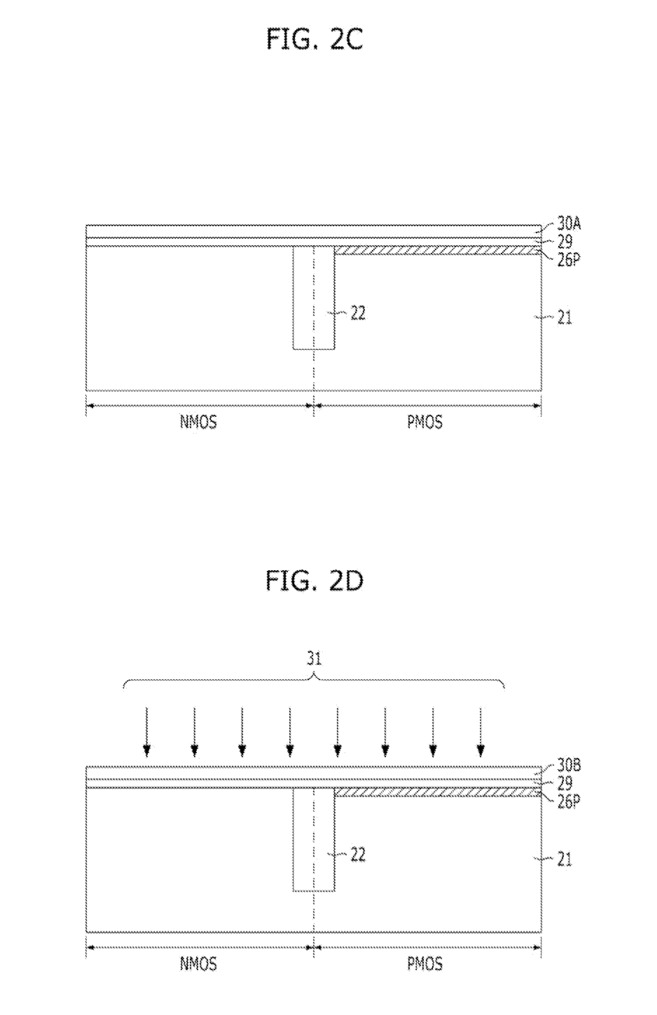

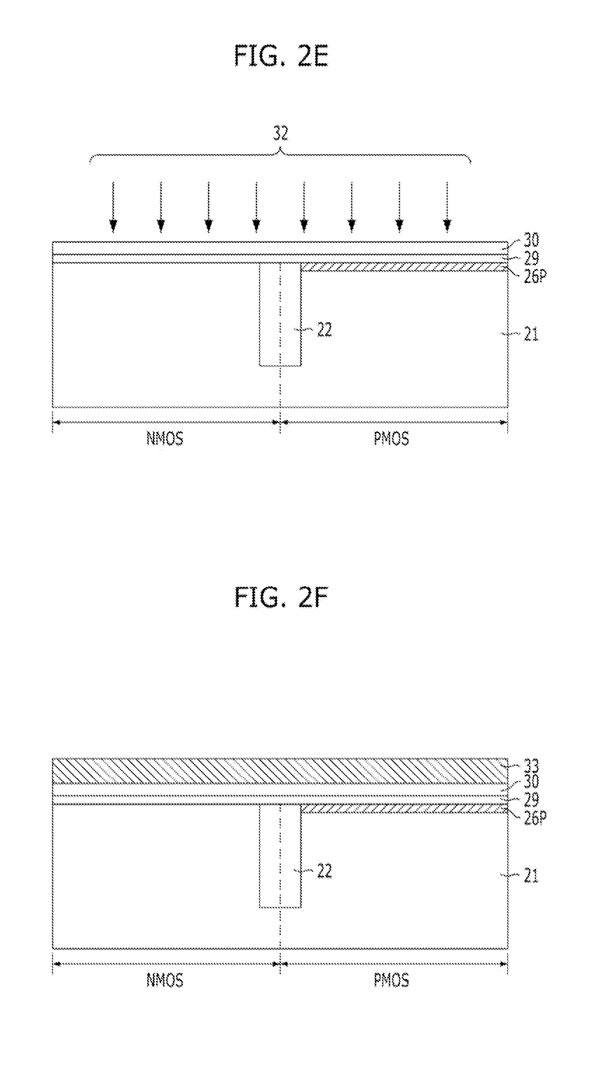

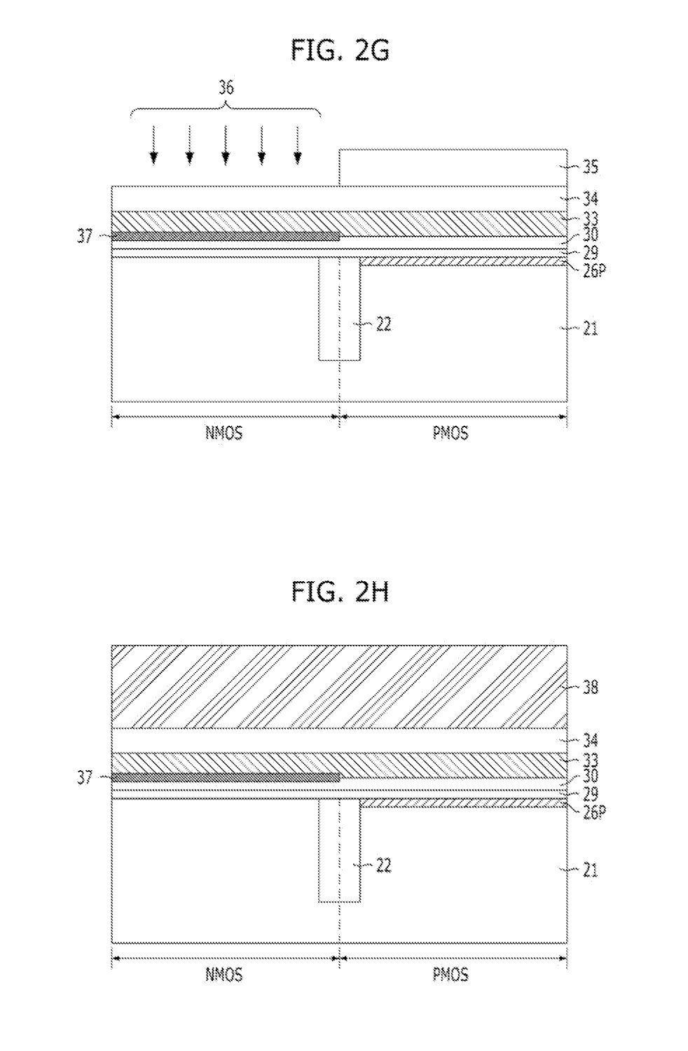

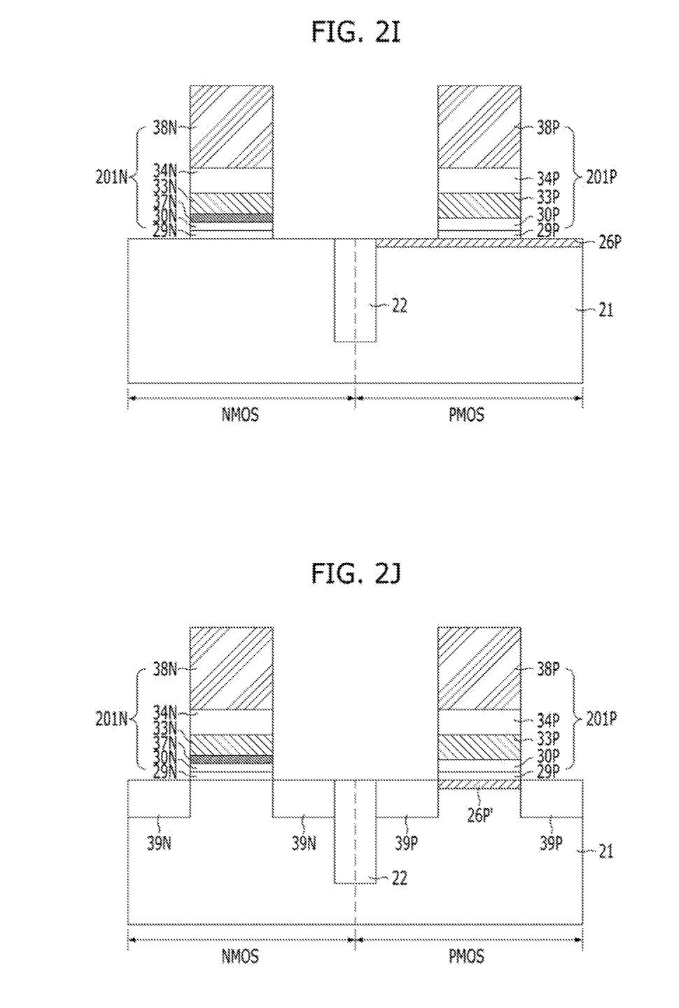

FIGS. 2A to 2J are diagrams illustrating a method for manufacturing a semiconductor device in accordance with an exemplary embodiment of the present invention. Hereinafter, in the embodiment of the present, a method for fabricating CMOS device will be described. The present invention is not limited within the CMOS device, and may be applied to a method for fabricating an N-channel transistor and a P-channel transistor. The PMOS transistor may include PMOSFET (hereinafter, referred to as ‘PMOS’). The NMOS transistor may include NMOSFET (hereinafter, referred to as ‘NMOS’).

As shown in FIG. 2A, a substrate 21 includes a plurality of regions on which a transistor is formed. The plurality of regions include a first region NMOS and a second region PMOS. The substrate 21 may include a semiconductor material. The substrate 21 may include a semiconductor substrate such as a silicon substrate, a silicon germanium substrate, and a silicon-on-insulator (SOI) substrate.

An element isolation region 22 is formed on the substrate by a shallow trench isolation (STI) process. For example, after a pad layer (not shown) is formed on the substrate 21, a trench is formed by etching the pad layer (not shown) and the substrate 21 using an element isolation mask (not shown). The element isolation region 22 is formed by gap-filling a dielectric material on the trench. The element isolation region 22 includes a wall oxide, a liner, and a gap-fill dielectric material which are sequentially formed. The liner may be formed by stacking silicon nitride and silicon oxide. The silicon nitride may include Si₃N₄ and the silicon oxide may include SiO₂. The gap-fill dielectric material may include spin on dielectric (SOD). In another embodiment, the element isolation region 22 may use the silicon nitride as the gap-fill dielectric material.

Next, a protection layer 23 is formed on an entire surface of the substrate 21. The protection layer 23 performs a screen function during an ion implant process. For example, the protection layer 23 minimizes a damage of the substrate when a dopent or other material is implanted on the substrate. The protection layer 23 may be formed by a thermal oxidation process. The protection layer 23 may include SiO₂. The protection layer 23 is referred to as ‘screen oxide’, and may be formed with a thickness of 50-100 Å.

A first mask pattern 24 is formed after the protection layer 23 is formed. The first mask pattern 24 may open any one of the first region NMOS and the second region PMOS. In this embodiment, the second region PMOS is opened by the first mask pattern 24.

The threshold voltage adjusting species are implanted on the second region PMOS using the first mask pattern 24 as an ion implant mask. This is referred to as a threshold voltage adjusting species implant 25. The threshold voltage adjusting species are materials for adjusting the threshold voltage of the P-channel transistor. The threshold voltage adjusting species may include the germanium. An ion implant may be applied to the threshold voltage adjusting species implant 25. The threshold voltage adjusting species implant 25 may be performed with energy of, for example, 1-10 KeV and dose of, for example, 1×10¹⁴-1×10¹⁷ atoms/cm². The threshold voltage adjusting species implant 25 may be performed on a channel region of the second region PMOS. If the dose of the threshold voltage adjusting species implant 25 is much higher or lower than a predetermined range, since the threshold voltage shift for acquiring a desired threshold voltage is much larger or smaller, it may be not suitable for acquiring a desired electric characteristic. Thus, the dose and energy of the threshold voltage adjusting species implant 25 may be suitably determined according to the threshold voltage shift within a range of 1×10¹⁴-1×10¹⁷ atoms/cm².

If the threshold voltage adjusting itplant 25 is performed as described above a threshold voltage adjusting region 26 having a predetermined depth below a surface of the substrate 21. For example, if the threshold voltage adjusting species are the germanium, a germanium containing region of a silicon germanium (SiGe) structure is formed by reacting with a silicon component of the substrate 21.

A well forming process and a channel forming process (not shown) may be performed before the threshold voltage adjusting species implant 25.

An N-type well is formed on the second region PMOS, and a P-type well is formed on the first region NMOS. The ion implant of a P-type dopent such as Boron (B) or Borondifluoride (BF₂) may be performed to form the P-type well. The ion implant of an N-type dopent such as phosphorus (P) and arsenic (As) may be performed to form the N-type well.

After the well forming process, the N-channel and the P-channel may be formed by the channel forming process. The N-channel is formed on the first region NMOS and the P-channel is formed on the second region PMOS. The ion implant of the N-type dopent such as phosphorus (P) and arsenic (As) may be performed to form the P-channel. The ion implant of the P-type dopent such as Boron (B) may be performed to form the N-channel. The channel forming process may be performed after the threshold voltage adjusting species implant 25. The threshold voltage is determined by implanting the N-type dopent on the channel region of the P-channel transistor, but it may be difficult to further reduce the threshold voltage. Thus, in the embodiment of the present invention, the threshold voltage may be further reduced by adding the germanium on the channel and adjusting an energy band gap.

As shown in FIG. 2B, the protection layer 23 is removed by a cleaning process. The protection layer 23 may be removed using a wet etching. For example, a hydrofluoric acid (HF) or a chemical having the hydrofluoric acid (HF) may be used by removing the protection layer 23 if the protection layer 23 includes silicon oxide.

Subsequently, a post process 27 is performed. The roughness of the threshold voltage adjusting region 26 may be improved by the post process 27. Moreover, the threshold voltage adjusting region 26 may be crystallized by the post process 27. In this embodiment of the present invention, the post process 27 may include a thermal process. The post process 27 may include a thermal oxidation process. For example, a sacrificial oxidation layer 28 may be formed by the post process 27. The sacrificial oxidation layer 28 may be formed with thickness of 30-100 Å at 750-900° C. temperature. The sacrificial oxidation layer 28 may include the silicon oxide.

A threshold voltage adjusting region 26P having a crystalline structure may be formed and the roughness of the threshold voltage adjusting region 26P having the crystalline structure may be improved by forming the sacrificial oxidation layer 28. The threshold voltage adjusting region 26P having a crystalline structure may be a germanium-rich region. For example, the threshold voltage adjusting region 26 having a silicon germanium structure becomes the threshold voltage adjusting region 26P having the crystalline structure of the germanium-rich according as the silicon may be consumed by the thermal oxidation process of the post process. The threshold voltage of the P-channel transistor may be adjusted to be lowered by forming the threshold voltage adjusting region 26P having the crystalline structure.

As shown in FIG. 2C, the sacrificial oxidation layer 28 is removed by a cleaning process using a solution having the hydrofluoric acid. By performing the cleaning process, the sacrificial oxidation layer 28 of a surface of the substrate 21 is removed, a dangling bond of the surface of the substrate 21 is passivated with hydrogen, and a natural oxidation is limited to grow until the post process is performed.

After an interface layer 29 is formed on the substrate 21, high-k materials 30A is formed on the interface layer 29. The interface layer 29 may include silicon oxide and silicon oxynitride. For example, the interface layer 29 may include SiO₂ and SiON. The interface layer 29 improves an electron mobility characteristic by improving an interface characteristic between the substrate 21 and the high-k materials 30A. The silicon oxide as the interface layer 29 may be grown by a wet process using ozone. Especially, if the silicon oxide as the interface layer 29 is grown by the wet process using the ozone and the high-k materials 30A are silicate materials having hafnium, hafnium silicate (HfSiO) having hafnium-rich material is formed. This increases a dielectric constant of the high-k materials 30A. The interface layer 29 is formed with thickness of 5-13 Å.

The high-k materials 30A may be formed with same materials on the first region NMOS and the second region PMOS. The high-k materials have a higher permittivity than the permittivity of SiO₂ used as a general gate permittivity, about 3.9. Moreover, the high-k materials 30A are thicker than SiO₂ and have a lower equivalent oxide thickness (EOT) than SiO₂. The high-k materials may have a higher permittivity than the interface layer 29.

The high-k materials include a metal containing material such as a metal oxide or a metal silicate. The metal oxide includes an oxide having a metal such as hafnium (Hf), aluminum (Al), lanthanum (La), zirconium (Zr) and the like. The metal oxide may include hafnium oxide, aluminum oxide, lanthanum oxide, zirconium oxide or the combination of these materials. For example, the metal oxide may include HfO₂, Al₂O₃, La₂O₃, ZrO₂ or the combination of these materials. The metal silicate includes the silicate having a metal such as hafnium (Hf) and zirconium (Zr). For example, the metal silicate hafnium silicate (HfSiO), zirconium silicate (ZrSiO) or the combination of these materials. Hereinafter, in the embodiment of the present invention, the hafnium silicate (HfSiO) may be used as the high-k materials 30A. A process is simplified by forming the high-k materials 30A on the first region NMOS and the second region PMOS at the same time. Meanwhile, the high-k materials 30A having different materials may be formed on the first region NMOS and the second region PMOS. A forming process of the high-k materials 30A may include a deposition technology suitable for materials to be deposited. For example, a chemical vapor deposition (CVD), a low-pressure CVD (LPCVD), a plasma-enhanced CVD (PECVD), a metal-organic CVD (MOCVD), an atomic layer deposition (ALD), a plasma enhanced ALD (PEALD) and the like may be used in the forming process of the high-k materials 30A. The ALD or PEALD may be used to form a uniform layer. The high-k materials 30A may be formed with the thickness of 15-60 Å.

As shown in FIG. 2D, the high-k materials 30A may be exposed in a nitridation process 31. The nitridation process 31 includes a plasma nitridation process. Thus, the nitrogen (N) is implanted on the high-k materials 30A. Hereinafter, the high-k materials having an implanted nitrogen is indicated as ‘30B’. For example, in case of the high-k materials 30A having the hafnium silicate (HfSiO), the high-k materials 308 of ‘HfSiON’ may be formed by the nitridation process. If the nitrogen is implanted on the metal silicate, the dielectric constant is increased and the crystallization of the metal silicate may be limited during the post thermal process. The plasma nitridation process may be performed at a temperature of 400-600° C. An argon gas (Ar) and a nitrogen gas (N₂) may be mixed and used as a reacting gas during a plasma nitridation process.

During the plasma nitridation process, the high-k materials 30A using the metal silicate becomes the high-k materials 30B of the metal silicate nitride by exposing the high-k materials 30A by the nitrogen plasma. Other gas may be used as a nitrogen supply source. For example, the nitrogen supply source may include ammonia (NH3), hydrazine (N₂H₄) and the like.

As shown in FIG. 2E, the high-k materials 30B of the metal silicate nitride is exposed by an anneal process 32. Since the anneal process is performed after the nitridation process 31, the anneal process is referred to as a post nitridation anneal. The hafnium silicate has a surface of a nitrogen-rich state by the plasma nitridation. If the anneal process 32 is performed, a nitrogen atom which is implanted on the hafnium silicate (HfSiO) may spread uniformly. The anneal process 32 may be performed under the nitrogen gas (N2) at 500-900° C.

After the anneal process 32 is performed, the high-k materials are indicated as ‘30’. Hereinafter, ‘30’ of FIG. 2E is referred to as a gate dielectric layer.

As described above, the high-k materials 30A is formed and the gate dielectric layer 30 is formed by the nitridation process 31 and the anneal process. The gate dielectric layer 30 includes the high-k materials 30A, and especially includes a metal silicate nitride. If the gate dielectric layer 30 is formed using the metal licate nitride, a dielectric constant may be increased, and the post thermal process limits the crystallization. The gate dielectric layer 30 includes a hafnium containing material.

As shown in FIG. 2F, a metal containing layer 33 is formed on the gate dielectric layer 30. The metal containing layer 33 may be formed an entire surface of the substrate 21 having the gate dielectric layer 30. The metal containing layer 33 may have effective work function adjusting species. The metal containing layer 33 has an effective work function suitable for the P-channel transistor by the effective work function adjusting species. Thus, the metal containing layer 33 may be a ‘P-type effective work function metal containing layer’. The P-type effective work function metal containing layer may include a material having an effective work function of 4.7 eV-5.2 eV. The metal containing layer 33 has a first effective work function which may be changed to a second effective work function higher than the first effective work function according to the effective work function adjusting species. For example, the first effective work function may include a midgap work function. The second effective work function has a value higher than 4.7 eV. Thus, the metal containing layer 33 becomes high effective work function materials. The effective work function adjusting species may include the nitrogen (N).

The metal containing layer 33 may include nitrogen-rich metal nitride. The nitrogen-rich metal nitride is a metal nitride having the nitrogen much more than a chemical composition ratio of the metal and the nitrogen. The metal nitride may include titanium nitride. The metal containing layer 33 may include titanium nitride having the effective work function adjusting species. The metal containing layer 33 may include the nitrogen as the effective work function adjusting species. Thus, the metal containing layer 33 may include nitrogen-rich titanium nitride. The nitrogen-rich titanium nitride (N-rich TiN) represents titanium nitride having the nitrogen much more than a chemical composition ratio of the titanium and the nitrogen. The titanium nitride (TiN) has different effective work function according to the composition ratio of the titanium and the nitrogen. For example, the nitrogen-rich titanium nitride has an effective work function suitable for the P-channel transistor. On the contrary, titanium-rich titanium nitride has an effective work function suitable for the N-channel transistor. Thus, the titanium-rich titanium nitride may have low effective work function. The nitrogen-rich titanium nitride may be formed using the physical vapor deposition (PVD). Thus, the combination of the titanium and the nitrogen included in the titanium nitride is easily adjusted. Since the metal containing layer 33 has the high effective work function suitable for the P-channel transistor, nitrogen-rich titanium nitride is formed as the metal containing layer 33. The combination of the titanium and the nitrogen is adjusted by selectively adjusting amount of the nitrogen of the nitrogen-rich titanium nitride. For example, the amount of the nitrogen may be adjusted to 20-200 sccm. Thus, the nitrogen-rich titanium nitride having the high effective work function of 4.7-5.1 eV may be formed by controlling the amount of the nitrogen. The nitrogen-rich titanium nitride may be formed by the ALD.

The effective work function adjusting species contained in the metal containing layer 33 may change the effective work function of the metal containing layer 33 and form dipole by coupling with other element. For example, effective work function adjusting species may have first electronegativity. The nitrogen used as the effective work function adjusting species has electronegativity of 3.04. Hereinafter, the effective work function adjusting species is referred to as ‘first element’. Thus, the metal containing layer 33 may include the metal and the first element. Especially, the metal containing layer 33 may include the first element which is over-contained.

As shown in FIG. 2G, a buffer layer 34 is formed on the metal containing layer 33. The buffer layer 34 is a material buffering an ion impact during the ion implant process. The buffer layer 34 may include a silicon containing material. The buffer layer 34 may include a silicon layer. The silicon layer may include an undoped silicon layer where a dopent is undoped. The buffer layer 34 may be formed with the thickness of 50-200 Å.

A dipole forming layer 37 is formed on an interface of the gate dielectric layer 30 and the metal containing layer 33 of the first region NMOS. The dipole forming layer 37 may include the second element which forms the dipole by being coupled with the first element included in the metal containing layer 33. The dipole forming layer 37 may be formed on a side of the metal containing layer 33 of the interface of the gate dielectric layer 30 and the metal containing layer 33.

An exemplary process for forming the dipole forming layer 37 will be described below.

A second mask pattern 35 is formed on the buffer layer 34. The second mask pattern 35 may open any one of the first region NMOS and the second region PMOS. Here, the second mask pattern 36 opens the first region NMOS in this embodiment of the present invention.

An ion implant 36 of the second element is performed using the second mask pattern as an ion implant mask. The second element may have electronegativity different from the first element of the metal containing layer 33. The second element may have a second electronegativity lower than that of the first element.

The second element may include arsenic (As) having the electronegativity of about 2.18. A dipole may be formed between the nitrogen and the arsenic by the electronegativity difference. The second element may include other elements instead of the arsenic (As). The second element may include an element which forms a dipole for reducing a threshold voltage of the N-channel transistor. The second element may include phosphorus (P), boron (B) and carbon (C) The second element may include an element for preventing the gate dielectric layer 30 from being degrading. That is, the second element may include an element which may be coupled with the first element and does not spread to the gate dielectric layer 30. Thus, the second element may include the arsenic (As). Since a spreading of the arsenic (As) is slow, it may be not easy for the arsenic (As) to spread to the gate dielectric layer 30. Thus, the ion implant of high density may be performed on the interface of the metal containing layer 33 and the gate dielectric layer 30.

The ion implant 36 of the second element may be performed with the energy of 1-10 KeV and the dose of 1×10¹⁴-1×10¹⁷ atoms/cm². The ion implant 36 of the second element is performed on the metal containing layer 33 and especially, may be performed on a contact region with the gate dielectric layer 30.

The dipole forming layer 37 is formed on the interface of the metal containing layer 33 and the gate dielectric layer 30 by the ion implant 36 of the second element. The dipole forming layer 37 includes the first element and the second element having different electronegativity from each other. The dipole is formed by the electronegativity difference between the first element and the second element. The threshold voltage of the N-channel transistor may be reduced by the dipole forming layer 37.

Since the ion implant 36 of the second element is performed on the metal containing layer 33, the dipole forming layer 37 may be the metal containing layer having the first element and the second element. For example, the dipole forming layer 37 may be the metal containing layer which includes the nitrogen (N) as the first element and the arsenic (As) as the second element. Moreover, the dipole forming layer 37 may include a metal nitride having the arsenic (As) or a nitrogen-rich titanium nitride having the arsenic (As). The dipole may be formed by coupling the arsenic (As) with the nitrogen included in the nitrogen-rich titanium nitride. Thus, the work function of the nitrogen-rich titanium nitride may be changed to be lowered. In conclusion, the effective work function is lowered by having the high effective work function suitable for the P-channel transistor on the gate stack body having the nitrogen-rich titanium nitride, coupling the arsenic (As) with the nitrogen-rich on the gate stack body of the N-channel transistor and forming the dipole.

As shown in FIG. 2H, the second mask pattern 35 is removed. A capping layer 38 is formed on an entire surface having the buffer layer 34. The capping layer 38 includes a silicon containing layer. The capping layer 38 may include a doped silicon layer. For example, the capping layer 38 may be an N-type silicon layer or a P-type silicon layer. The buffer layer 34 and the capping layer 38 may perform a function of an oxidation prevention layer for preventing the oxidation of the metal containing layer 33.

Since the capping layer 38 may include the doped silicon layer, the capping layer formed on the first region NMOS and the second region PMOS may be the doped silicon layer. A conductive type of the doped silicon layer may be an N-type or a P-type irrespective of the N-channel transistor and the P-channel transistor. That is, an N-type doped silicon layer or a P-type doped silicon layer may be formed on the first region NMOS. The N-type doped silicon layer or the P-type doped silicon layer may be formed on the second region PMOS. Moreover, the N-type doped silicon layer may be formed on all of the first region NMOS and the second region PMOS, or the P-type doped silicon layer may be formed on all of the first region NMOS and the second region PMOS. In conclusion, the capping layer 38 having the same materials and conductive types may be formed on the first region NMOS and the second PMOS.

A low resistance metal containing layer (not shown) may be further formed on the capping layer 38. The low resistance metal containing layer may include tungsten. The low resistance metal lowers a resistance of the gate stack body.

As shown in FIG. 2I, a gate patterning process performed using a gate mask (not shown).

Thus, a first gate stack body 201N is formed on the substrate of the first region NMOS, and a second gate stack body 201P is formed on the substrate of the second region PMOS. A first gate stack body 201N includes a first gate dielectric 30N, a dipole forming layer 37N, a first metal containing gate electrode 33N, the first buffer layer 34N and a first capping layer 38N which are sequentially stacked. A second gate stack body 201P includes a second gate dielectric 30P, a second metal containing gate electrode 33P, a second buffer layer 34P and a second capping layer 38P which are sequentially stacked. The first gate stack body 201N of the first region NMOS has different materials from the second gate stack body 201P of the second region PMOS. The first gate stack body 201N and the second gate stack body 201P further includes a first interface layer 29N and a second interface layer 29P formed below the first gate dielectric layer 30N and the second gate dielectric layer 30P, respectively. A threshold in voltage adjusting region 26P having the germanium is formed on the substrate 21 (that is, P-channel) below the second gate stack body 201P.

As shown in FIG. 2J, subsequently, a general process widely known to a person in the art, may be performed. For example, a source/drain forming process may be performed. The source/drain includes an N-type source/drain 39N and a P-type source/drain 39P. The N-type source/drain 39N is formed on the first region NMOS. The P-type source/drain 39P is formed on the second region PMOS. A threshold voltage adjusting region 26P′ is formed on the P-channel between a P-type source and a P-type drain of the second region PMOS.

As described above, the first transistor and the second transistor are formed by forming the N-type source/drain 39N and the P-type source/drain 39P. The first transistor includes the first gate stack body 201N, and the second transistor includes the second gate stack body 201P. The first transistor is the N-channel transistor having the NMOS, and the second transistor is the P-channel transistor having the PMS. The threshold voltage adjusting region 26P is formed on the channel region of the second transistor.

The dipole forming layer 37N of the first gate stack body 201N is formed on an interface of the first gate dielectric layer 30N and the first metal containing gate electrode 33N. Thus, the threshold voltage of the N-channel transistor may be reduced. More specifically, the dipole is formed according to the electronegativity difference of elements included in the dipole forming layer 37N formed on the interface of the first gate dielectric layer 30N and the first metal containing gate electrode 33N. This dipole may reduce the threshold voltage of the N-channel transistor.

Since the threshold voltage adjusting region 26P′ is formed below the second gate stack body 201P, the threshold voltage of the P-channel transistor may be reduced. More specifically, the energy band gap may be reduced by forming a germanium-rich region on the P-channel. Thus, the threshold voltage may be adjusted to be suitable for the P-channel transistor. Moreover, since the second gate stack body 201P includes the second metal containing gate electrode 33P having the effective work function adjusting species, the threshold voltage of the P-channel transistor may be further reduced.

In conclusion in the integrated process of the CMOS device in accordance with the embodiment of the present invention, the threshold voltages of the N-channel transistor and the P-channel transistor may be independently adjusted.

The CMOS device in accordance with the embodiment of the present invention may be applied to a dynamic random access memory (DRAM), a static random access memory (SRAM), a flash memory, a ferroelectric random access memory (FeRAM), a magnetic random access memory (MRAM) and a phase change random access memory (PRAM).

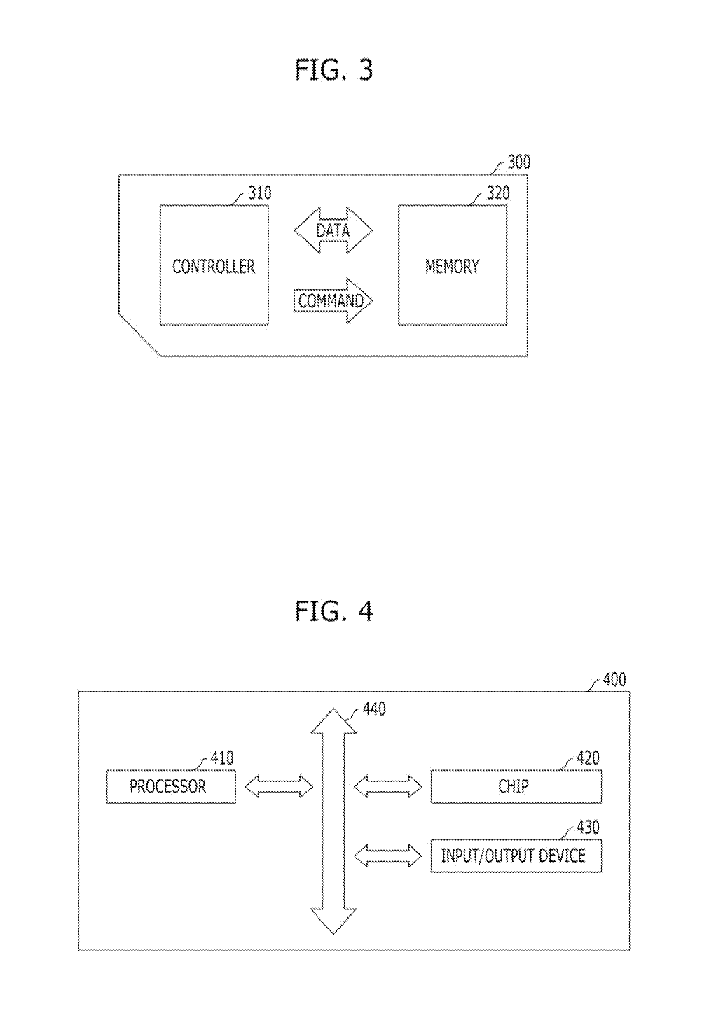

FIG. 3 is a block diagram showing a memory card in accordance with an exemplary embodiment of the present invention.

Referring to FIG. 3, a memory card 300 includes a controller 310 and a memory 320. The controller 310 and the memory 320 transceives electrical signals to each other. For example, the memory 320 transceives data to the controller 310 in response to a command of the controller 310. Thus, the memory card 300 stores on the memory 320 or outputs data stored on the memory to an external device. The CMOS device described above may be included in a specific portion of the memory 320. The memory card 300 may be used as data storage medium of various portable devices. For example, the memory card 300 may include a memory stick card, a smart media (SM) card, a secure digital (SD) card, a mini secure digital (SD) card or a multimedia card (MMC).

FIG. 4 is a block diagram showing an electronic system accordance with an exemplary embodiment of the present invention.

Referring to FIG. 4, an electronic system 400 includes a processor 410, an input/output device 430 and a chip 420 which communicate data with each other through a data communication. The processor 410 performs a program, and controls the electronic system 400. The input/output device 430 may be used in inputting or outputting data of the electronic system 400. The electronic system 400 is coupled with an external device, e.g., a personal computer, or a network through the input/output device 430, and communicates data with the external device. The chip 420 stores codes and data for operation of the processor 410 and performs an operation which is ordered by the processor 410. For example, the chip 420 may include CMOS device. The electronic system 400 may include various electronic control devices having the chip 420 such as a mobile phone, an MP3 player, a navigator, a solid state disk (SSD), household appliances and the like.

As described above, a semiconductor device and method for manufacturing the same in accordance with the various embodiments of the present invention may independently adjust a threshold voltage of an N-channel transistor and a P-channel transistor. The threshold voltage of the P-channel transistor may be reduced by containing the germanium on the P-channel region and reducing the energy band gap of the P-channel region. The threshold voltage may be further reduced by using the high effective work function materials having the effective work function adjusting species as the metal containing gate electrode, and increasing the effective work function of the gate stack body.

The threshold voltage of the N-channel transistor may be reduced by forming the dipole forming layer on the interface of the gate dielectric layer and the metal containing gate electrode. Moreover, since an element for forming the dipole is added on the metal containing gate electrode, the reliability or the permittivity of the gate dielectric layer may be prevented from being changed.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
an N-channel transistor including a first gate dielectric layer, a first metal containing gate electrode and a dipole forming layer, wherein the first metal containing gate electrode is formed on the first gate dielectric layer, and the dipole forming layer is formed on an interface of the first gate dielectric layer and the first metal containing gate electrode; and
a P-channel transistor including a channel region, a second gate dielectric layer and a second metal containing gate electrode, wherein the channel region has threshold voltage adjusting species, the second gate dielectric layer is formed on the channel region, and the second metal containing gate electrode has effective work function adjusting species of the second gate dielectric layer.

2. The semiconductor device of claim 1, wherein the second metal containing gate electrode has a first effective work function, and the effective work function adjusting species is changed to a second effective work function higher than the first effective work function.

3. The semiconductor device of claim 1, wherein the effective work function adjusting species include nitrogen.

4. The semiconductor device of claim 1, wherein the first metal containing gate electrode and the second metal containing gate electrode have same materials.

5. The semiconductor device of claim 1, wherein the second metal containing gate electrode includes a metal nitride having the effective work function adjusting species.

6. The semiconductor device of claim 1, wherein the second metal containing gate electrode includes a titanium nitride having nitrogen-rich as the effective work function adjusting species.

7. The semiconductor device of claim 1, wherein the threshold voltage adjusting species include germanium.

8. The semiconductor device of claim 1, wherein the dipole forming layer includes a first element and a second element having electronegativity lower than the first element.

9. The semiconductor device of claim 1, wherein the dipole forming layer includes a metal containing layer having nitrogen and arsenic.

10. The semiconductor device of claim 1, wherein the dipole ing layer includes a metal nitride having doped arsenic.

11. The semiconductor device of claim 1, wherein the dipole forming layer includes a metal nitride having nitrogen-rich, and the metal nitride further includes an element having electronegativity lower than the electronegativity of the nitrogen.

12. A transistor, comprising:
a substrate;
a gate dielectric layer configured to be formed on the substrate; and
a metal nitride configured to have a gate electrode having nitrogen-rich,
wherein the gate electrode is formed on the gate dielectric layer, and the metal nitride further includes an element which is implanted to form a dipole on an interface of the gate dielectric layer by being coupled with nitrogen-rich.

13. The transistor of claim 12, wherein the element is selected to form the dipole for shifting a threshold voltage of the transistor.

14. The transistor of claim 12, wherein the element includes electronegativity lower than the nitrogen.

15. The transistor of claim 12, wherein the element includes arsenic.

16. The transistor of claim 12, wherein the metal nitride includes nitrogen-rich titanium nitride having nitrogen much more than a chemical combination ratio of titanium and nitrogen.

17. A semiconductor device, comprising:
an N-channel transistor including:
a first gate dielectric layer;
a first metal containing gate electrode configured to be formed on the first gate dielectric layer; and
a dipole forming layer configured to be formed as an interface of the first gate dielectric layer and the first metal containing gate electrode;
a P-channel transistor including:
a channel region including threshold voltage adjusting species,
a second gate dielectric layer configured to be formed on the channel region; and
a second metal containing gate electrode including effective work function adjusting species of the second gate dielectric layer; and
an isolation region configured to electrically isolate the N-channel transistor from the P-channel transistor.

18. The semiconductor device of claim 17, wherein the P-channel transistor includes a threshold voltage adjusting region configured to be formed in a substrate below the second metal containing gate electrode.

19. The semiconductor device of claim wherein the threshold voltage adjusting region includes germanium-rich material.
